(19) United States
(12) Patent Application Publication
(10) Pub. No.: US 2005/0045903 A1
(43) Pub. Date: Mar. 3, 2005

(54) Surface-mounted light-emitting diode and method

(76) Inventors: Tomoaki Abe, Tokyo (JP); Hisashi Suwa, Tokyo (JP)

Correspondence Address: CERMAK & KENEALY, LLP, 23 W. Myrtle St, Alexandria, VA, 22301, US

(21) Appl. No.: 10/722,556

(22) Filed: Nov. 28, 2003

(30) Foreign Application Priority Data
Aug. 29, 2003 (JP) 2003-307517

(51) Int. Cl. H01L 33/00

(52) U.S. Cl. 257/100

(57) ABSTRACT

A surface-mounted light-emitting diode can be employed as a light source for cell phones and other electronic devices and contributes to the downsizing of electronic devices. An optically transmissive resin can have a surface provided with metallic films formed thereon and be employed to seal an LED chip and wires therein. The LED chip can be mounted on the metallic film via a conductive adhesive to achieve an electrical connection between a lower electrode of the LED chip and the metallic film. The wires can be connected between upper electrodes of the LED chip and the metallic films to achieve electrical conduction between the upper electrodes of the LED chip and the metallic films.

This invention claims the benefit of Japanese patent application No. 2003-307517, filed on Aug. 29, 2003, which is hereby incorporated by reference.

### BACKGROUND OF THE INVENTION

1. Field of the Invention

The present invention relates to a light-emitting diode and more particularly to a surface-mounted light-emitting diode that contains no printed-circuit board and is available in illumination light sources for compact and lightweight devices such as cell phones and other electronic devices.

2. Description of the Related Art

With recent efforts to downsize and reduce the weight of electronic devices, different approaches have been aggressively developed for surface mounting aimed at downsizing a light-emitting diode (LED). A conventional structure of a surface-mounted LED includes an insulator substrate that provides both surfaces with a pair of metallic conductor patterns that are electrically connected via a through-hole to form a double-sided through-hole printed-circuit board. An LED chip is mounted on one of the metallic conductor patterns via a conductive adhesive to secure the LED chip on the double-sided through-hole printed-circuit board and to allow a lower electrode on the LED chip to electrically conduct to the metallic conductor pattern. An upper electrode on the LED chip is electrically connected via a wire to the other metallic conductor pattern that is formed on the same surface of the double-sided through-hole printed-circuit board as that which is provided with the LED chip mounted thereon.

The LED chip and the wire are sealed in an optically transmissive resin for protection from extraneous stresses, such as mechanical vibrations and impacts, and from external environments, such as moisture, dust and dirt. In addition, the optically transmissive resin has a lens effect to control distribution of light emitted from the LED chip.

In this type of surface-mounted LED, the LED-chip-mounted, double-sided through-hole printed-circuit board has metallic conductive patterns formed on the opposite surface and the sides thereof, which are soldered on a mounting board. When a forward or positive voltage is applied across the LED chip to convert electric energy into optical energy, it emits light (see Japanese Patent Application Publication No.: JP-A-9/181359, page 2 and FIG. 12, for example, the disclosure of which is generally understood by those skilled in the art.

In another arrangement, a semiconductor element is sealed in a resinous package that is integrally provided with a projection having a metallic film formed thereon. The metallic film is electrically connected to an electrode pad provided on the upper surface of the semiconductor element (see Japanese Patent No.: 3007833, pages 5-6 and FIG. 1, for example, the disclosure of which is generally understood by those skilled in the art).

The surface-mounted LED disclosed in JP-A-9/181359 requires the use of the double-sided through-hole printed-circuit board as a necessary condition for mounting the LED chip. The double-sided through-hole printed-circuit board, however, has a thickness of at least 0.1 mm, which is a factor that interferes with the goal of thinning the surface-mounted LED.

When the surface-mounted LED is mounted as a circuit component, it is required to ensure adequate space between the surface-mounted LED and the surface-mounted components including the surface-mounted LED. The space is employed for solder fillets to solder the surface-mounted LED on a mounting board. An accumulated area of the fillets adds constraints to improving the component density mounted on the mounting board.

A sharp variation in temperature on thermosetting and cooling of the sealing resin for the surface-mounted LED, or on heating and cooling of the solder reflow, may cause a stress between the double-sided through-hole printed-circuit board and the sealing resin, which have a difference in thermal expansion coefficient. The stress results in quality-related malfunctions such as breaks in the LED chip, wire disconnection, and peel at the interface between the double-sided through-hole printed-circuit board and the sealing resin.

Such a surface-mounted LED is not generally manufactured individually. Rather, many LED chips are mounted on the double-sided through-hole printed-circuit board. Then, electrodes formed on each LED chip are connected to conductive patterns formed on the double-sided through-hole printed-circuit board via wires to achieve electrical connection there between. Thereafter, they are integrally sealed in an optically transmissive resin and finally cut into individual chips. In this case, cut burrs may arise at the metallic conductive patterns on the individualized surface-mounted LED. Such burrs inhibit the solder from elevating onto the metallic conductive patterns on the surface-mounted LED, resulting in insufficient soldering between the surface-mounted LED and the mounting board.

The semiconductor device disclosed in Japanese Patent No.: 3007833 is not configured to target a light-emitting element as the semiconductor element sealed in the resinous package. Therefore, any improvements are not applied in light extraction efficiency when a semiconductor light-emitting element is mounted, and are not applied in constructions associated with optics to control distribution of light. Accordingly, a light source has a poor optical characteristic.

The present invention has been made in consideration of the above and other problems and accordingly provides a thin, high-quality, high-density mountable, surface-mounted light-emitting diode excellent in optical characteristics.

### SUMMARY OF THE INVENTION

To solve the above and other problems, an aspect of the present invention is directed to a surface-mounted light-emitting diode comprising: a light-emitting diode chip sealed in an optically transmissive resin; a plurality of metallic films formed on different locations in a surface of the optically transmissive resin; and a plurality of electrodes formed on the light-emitting diode chip, wherein the electrodes are connected to the respective metallic films to achieve electrical conduction there between.

Another aspect of the invention includes the light-emitting diode chip mounted on a first metallic film of the metallic films to achieve electrical conduction between a lower electrode on the light-emitting diode chip and the first metallic film, and wherein wires having portions at one end connected to one or two upper electrodes on the light-emitting diode chip and portions at the other end connected to a second metallic film or a second and a third metallic films of the metallic films are provided to achieve electrical conduction between the one or two upper electrodes on the light-emitting diode chip and the second metallic film or the second and third metallic films of the metallic films.

Another aspect of the invention includes a device in which at least the first metallic film of the metallic films is formed in a conical shape with a reflective inner surface, and wherein the light-emitting diode chip is mounted on the bottom thereof.

Another aspect of the invention includes a layer of optically transmissive resin containing a fluorescent material dispersed therein formed inside the conical shape to cover the light-emitting diode chip.

Yet another aspect of the invention includes a layer of optically transmissive resin containing a diffuser dispersed therein formed inside the conical shape to cover the light-emitting diode chip.

Another aspect of the invention includes an optically transmissive resinous lens formed above the light-emitting diode chip.

Another aspect of the invention includes at least the first metallic film of the metallic films being planar.

Another aspect of the invention includes the light-emitting diode chip mounted on an insulator member, and wherein wires having portions at one end connected to one or two upper electrodes on the light-emitting diode chip and portions at the other end connected to a second metallic film or a second and a third metallic films of the metallic films are provided to achieve electrical conduction between the one or two upper electrodes on the light-emitting diode chip and the second metallic film or the second and third metallic films of the metallic films.

Another aspect of the invention includes an optically transmissive resinous lens formed above the light-emitting diode chip.

Another aspect of the invention includes a resist layer formed on the same surface as the metallic-films-formed surface of the optically transmissive resin except for the metallic-films-formed portions.

Another aspect of the invention includes a light-emitting diode that has: a light-emitting diode chip located adjacent an optically transmissive resin; at least one metallic film formed directly on a surface of the optically transmissive resin; and at least one electrode located on the light-emitting diode chip, wherein the electrode is connected to the metallic film to achieve electrical conduction there between.

In another aspect of the invention, light-emitting diode chip is mounted on another metallic film to achieve electrical conduction between a lower electrode on the light-emitting diode chip and the another metallic film, and at least one wire is connected between the at least one upper electrode on the light-emitting diode chip and the at least one metallic film to achieve electrical conduction between the at least one upper electrode on the light-emitting diode chip and the at least one metallic film.

In another aspect of the invention a method of making a light-emitting diode, can include: providing a substrate with recesses; forming a plurality of metallic films in the recesses of the substrate; mounting an LED chip to one of the metallic films; connecting a wire between the LED chip and another one of the metallic films to achieve an electric connection between an electrode on the LED chip and the another one of the metallic films; placing a resin on the LED chip and metallic films; and removing the substrate.

Additional features, advantages, and embodiments of the invention may be set forth or apparent from consideration of the following detailed description, drawings, and claims. Moreover, it is to be understood that both the foregoing summary of the invention and the following detailed description are exemplary and intended to provide further explanation without limiting the scope of the invention as claimed.

### BRIEF DESCRIPTION OF THE DRAWINGS

The present invention will be more fully understood from the following detailed description with reference to the accompanying drawings, in which:

FIG. 1 shows exemplary process steps for a surface-mounted light-emitting diode according to an embodiment of the present invention in cross-sectional views of: (a) forming recesses in a substrate; (b) forming metallic films on inner surfaces of the recesses; (c) mounting an LED chip on the bottom of one of the recesses; (d) connecting upper electrodes on the LED chip to the metallic layers in the recesses via wires; (e) applying an optically transmissive resin to seal the inside of the recesses and the upper surface of the substrate; and (f) releasing the sealing resin from the substrate;

FIG. 2 is a perspective view of the surface-mounted light-emitting diode seen from above according to the embodiment of FIG. 1;

FIG. 3 is a perspective view of the surface-mounted light-emitting diode seen from below according to the embodiment of FIG. 1;

FIG. 4 is a cross-sectional view of a surface-mounted light-emitting diode according to another embodiment of the present invention;

FIG. 5 is a cross-sectional view of a surface-mounted light-emitting diode according to another embodiment of the present invention;

FIG. 6 is a cross-sectional view of a surface-mounted light-emitting diode according to another embodiment of the present invention;

FIG. 7 is a perspective view of the surface-mounted light-emitting diode seen from above according to the embodiment of FIG. 6;

FIG. 8 is a perspective view of the surface-mounted light-emitting diode seen from below according to the embodiment of FIG. 6; and

FIG. 9 is a cross-sectional view of a surface-mounted light-emitting diode according to another embodiment of the present invention.

### DETAILED DESCRIPTION OF PREFERRED EMBODIMENTS

The present invention provides a thinned surface-mounted light-emitting diode achieved in an arrangement that does not require a printed-circuit board to be used.

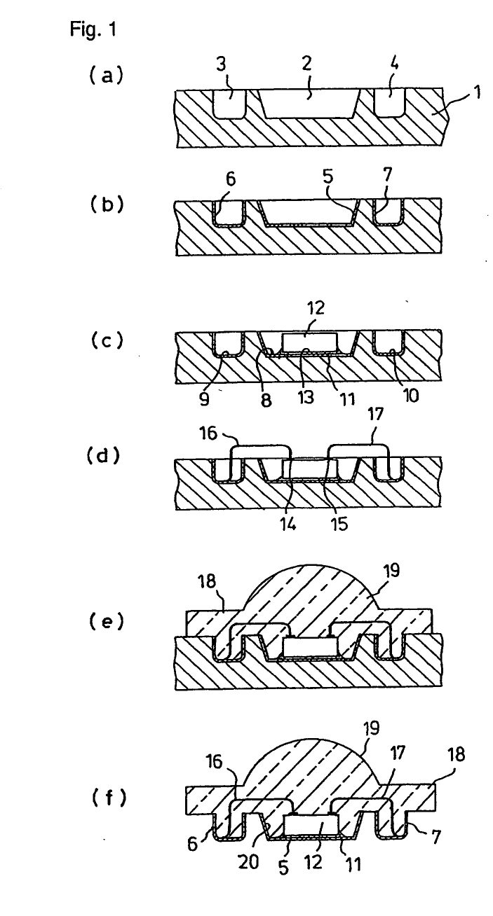

Embodiment of FIGS. 1-3

Preferred embodiments of the present invention will be described in detail below with reference to FIGS. 1-9 (denoting the same portions with the same reference numerals). It should be appreciated that the below-described embodiments are simply specified examples, which are given various preferable technical limitations. Accordingly, the scope of the present invention is not limited in these embodiments unless a special description is given to limit the present invention in the following explanation. Moreover, additional embodiments may exist that capture the spirit and scope of the claimed invention.

Prior to the explanation of the preferred physical embodiments of the present invention, exemplary process steps of the invention for achieving the physical embodiments of the present invention are described with reference to FIG. 1(a)-(f). Thereafter, several preferred physical embodiments of the invention will be described. As shown in FIG. 1(a), a metallic substrate 1, for example, composed of copper can be employed to form recesses 2, 3 and 4 by chemical etching, mechanical cutting or pressing with a mold. As shown in FIG. 1(b), metallic films 5, 6 and 7, for example, composed of gold can be formed on inner surfaces in the recesses 2, 3 and 4 by plating or evaporating. As shown in FIG. 1(c), an LED chip 12 can be mounted in the recess 2 on the bottom having the metallic film 5 formed thereon via a conductive adhesive 11 to achieve an electric connection between a lower electrode on the LED chip 12 and the metallic film 5. As shown in FIG. 1(d), wire portions at one end of wires 16, 17 can be connected to upper electrodes 14, 15 on the LED chip 12. In addition, wire portions at the other end of the wires 16, 17 can be connected to the metallic films 6, 7 on the bottoms 9, 10 in the recesses 3, 4, which are different from the recess 2 that contains the LED chip mounted therein. As a result, electric connections are achieved between the upper electrodes 14, 15 on the LED chip 12 and the metallic films 6, 7. As shown in FIG. 1(e), an optically transmissive resin 18 can be molded on the upper surface of the substrate 1 for filling the recesses 3, 4, surrounding the wires 16, 17, and forming a lens 19. The metallic films 5, 6, 7 and the optically transmissive resin 18 that all contact the substrate 1 can be separated from the substrate 1 to finish a product as shown in FIG. 1(f).

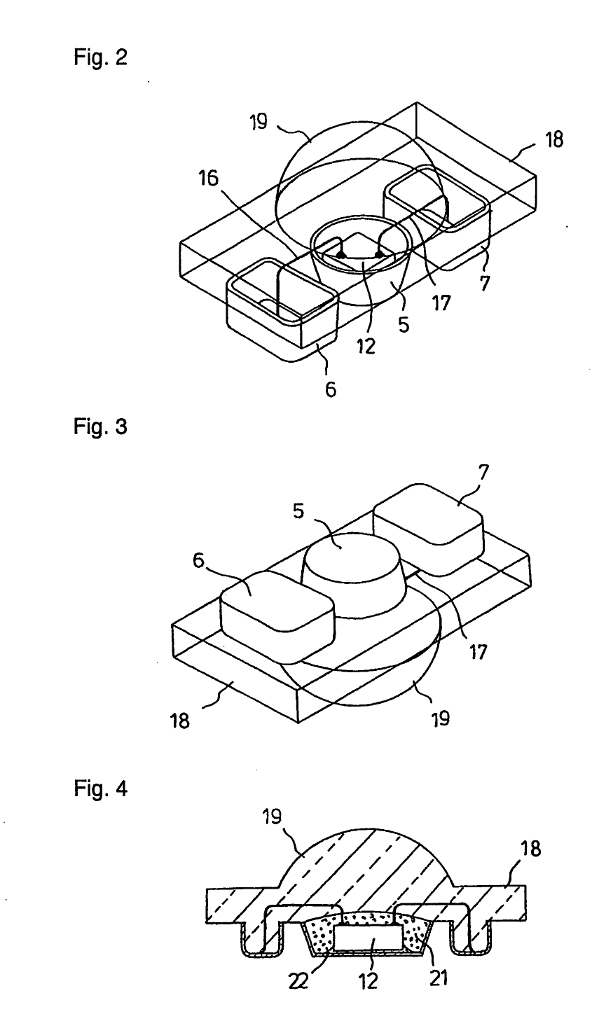

FIG. 1(f) is a cross-sectional view of an embodiment of the present invention. FIG. 2 is a perspective view as seen from above, of the embodiment of FIG. 1. FIG. 3 is a perspective view as seen from below, of the embodiment of FIG. 1. The LED chip 12 and the wires 16, 17 can be sealed in the optically transmissive resin 18. The LED chip 12 is preferably mounted on the metallic film 5 via the conductive adhesive 11 to electrically connect the lower electrode 13 on the LED chip 12 to the metallic film 5. The upper electrodes 14, 15 on the LED chip 12 can be connected at one end of wires 16, 17, and the metallic films 6, 7 can be connected at the other end of the wires 16, 17. Consequently, the upper electrodes 14, 15 on the LED chip 12 can be electrically connected to the metallic films 6, 7. As shown, not only can the metallic film 5 that is electrically connected to the lower electrode 13 on the LED chip 12 be formed on the surface of the optically transmissive resin 18, but the metallic films 6, 7 that are electrically connected to the upper electrodes 14, 15 on the LED chip 12 can also be formed on the surface of the optically transmissive resin 18.

Such a surface-mounted LED is not configured such that a printed-circuit board is required to mount an LED chip thereon (as is the conventional surface-mounted LED). Instead, the surface-mounted LED can include an optically transmissive resin that surrounds an LED chip therein in place of using of the printed-circuit board. Accordingly, the present structure is capable of thinning the surface-mounted LED more than the conventional structures.

The recess 2 in the substrate 1 for mounting the LED chip 2 therein may be formed in a conical shape. The inner surface of the recess 2 may be coated with a reflective material such as gold, silver, aluminum or the like to form a reflective surface 20. In this case, light emitted from the side of the LED chip 12 that is directed toward the reflective surface 20 is reflected at the reflective surface 20 and directed toward the optically transmissive resinous lens 19 located above the LED chip 12. This light can be mixed with other light emitted from the LED chip 12 and directed toward the inner surface of the optically transmissive resinous lens 19. The mixed light can be refracted at the emission surface of the lens 19 toward the optical axis of the LED chip and emitted externally through the lens.

Embodiment of FIG. 4

FIG. 4 is a cross-sectional view showing another embodiment of the invention. The basic structure of this embodiment is the same as that of the embodiment of FIGS. 1-3, except for a wavelength conversion layer 22 that includes a fluorescent material 21 dispersed in an optically transmissive resin. The wavelength conversion layer 22 can be provided in the conical recess 2 such that the LED chip 12 mounted in the conical recess 2 is immersed therein. If the LED chip 12 emits a blue light, a fluorescent material 21 can be employed that can wavelength-convert the blue light into its complementary yellow light when it is excited with the blue light. In this case, the blue light emitted from the LED chip 12 excites the fluorescent material 21 to create a wavelength-converted yellow light, which is additionally mixed with the blue light emitted from the LED chip 12 to yield a white light. When the light emitted from the LED chip 12 is blue light, two different fluorescent materials 21 may be employed in mixture that can wavelength-convert the blue light into respective green and red lights when they are excited with the blue light. In this case, the blue light emitted from the LED chip 12 excites the fluorescent materials 21 to create the wavelength-converted green and red lights, which are additionally mixed with the blue light emitted from the LED chip 12 to yield a white light. When the light emitted from the LED chip 12 is an ultraviolet light, three different fluorescent materials 21 may be employed in mixture that can wavelength-convert the ultraviolet light into respective blue, green and red lights when they are excited with the ultraviolet light. In this case, the ultraviolet light emitted from the LED chip 12 excites the fluorescent materials 21 to create the wavelength-converted blue, green and red lights, which are additionally mixed with each other to yield a white light.

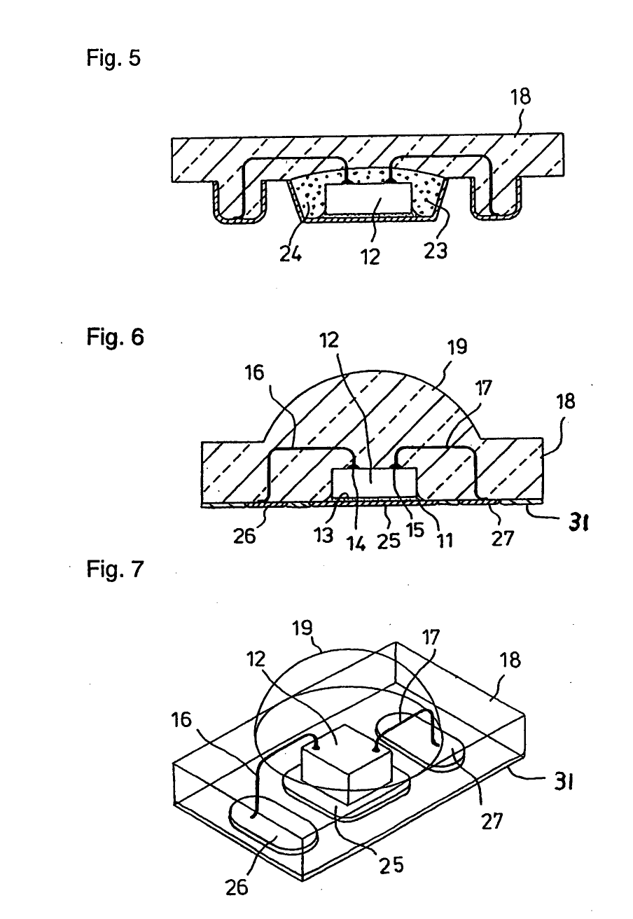

Embodiment of FIG. 5

FIG. 5 is a cross-sectional view showing another embodiment. Instead of including the wavelength conversion layer 22 of the embodiment of FIG. 4, the embodiment of FIG. 5 includes a light diffusive layer 24 that can include a diffuser 23 dispersed in an optically transmissive resin. The light diffusive layer 24 can be provided in the recess 2 such that the LED chip 12 mounted in the recess 2 is immersed therein. In this case, the light emitted from the LED chip 12 is diffused substantially uniformly to achieve approximately uniform light distribution emission. Preferably, the optically transmissive resin has a flat emission surface, not shaped in the form of a lens, to achieve a better diffusion effect.

Embodiment of FIG. 6

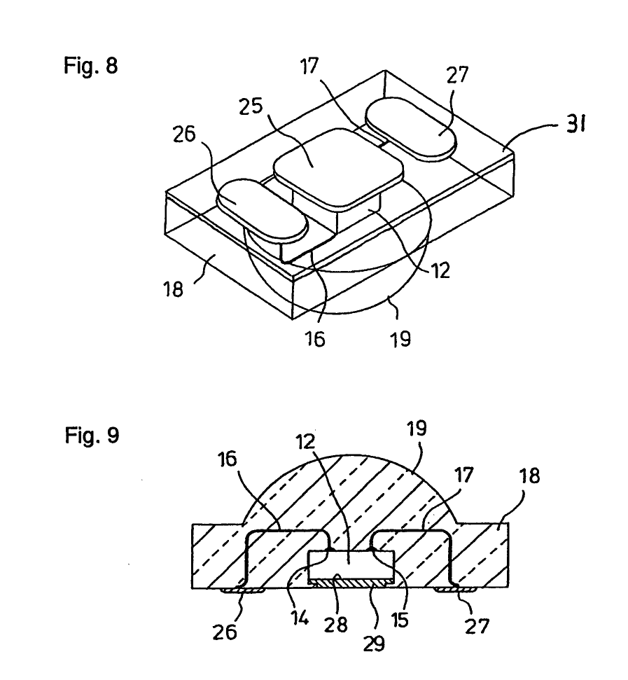

FIG. 6 is a cross-sectional view showing another embodiment of the invention. FIG. 7 is a perspective view of the embodiment of FIG. 6 as seen from above. FIG. 8 is a perspective view of the embodiment of FIG. 6 as seen from below. The LED chip 12 and the wires 16, 17 can be sealed in the optically transmissive resin 18. The LED chip 12 is preferably mounted on the metallic film 25 via the conductive adhesive 11 to electrically connect the lower electrode 13 on the LED chip 12 to the metallic film 25. One end of the wires 16, 17 can be connected to the upper electrodes 14, 15 on the LED chip 12, and the other end of the wires 16, 17 can be connected to the metallic films 26, 27. Consequently, the upper electrodes 14, 15 on the LED chip 12 can be electrically connected to the metallic films 26, 27. As shown, not only can the metallic film 25 that is electrically connected to the lower electrode 13 on the LED chip 12 be formed on the surface of the optically transmissive resin 18, but the metallic films 26, 27 that are electrically connected to the upper electrodes 14, 15 on the LED chip 12 can also be formed on the surface of the optically transmissive resin 18.

In the embodiment of FIGS. 6-8, the metallic films 25, 26, 27 can be planar in shape. Thus, the light emitted from the LED chip 12 exits directly from the optically transmissive resin. In this case, the sealing of the optically transmissive resin 18 may be applied to form the lens 19 above the LED chip 12 to collect the light rays emitted from the LED chip 12 and to guide them. Alternatively, the optically transmissive resin 18 may be formed with a flat emission surface to refract the light that reaches the emission surface of the optically transmissive resin 18 as such and guide it. In addition, an optional reflective member that forms a resist layer 31 may be formed on a surface of the optically transmissive resin 18 at various locations to enhance the external reflection of light from the LED chip.

Embodiment of FIG. 9

FIG. 9 is a cross-sectional view showing another embodiment of the invention. In this embodiment, an insulator member 29 can be disposed below the bottom 28 of the LED chip 12. The upper electrodes 14, 15 on the LED chip 12 can be connected to ends of the wires 16, 17. The metallic films 26, 27 can be connected to other ends of the wires 16, 17 to achieve an electric connection between the upper electrodes 14, 15 on the LED chip 12 and the metallic films 26, 27. These metallic films 26, 27 are preferably the only ones that are formed on the surface of the optically transmissive resin 18 in this embodiment. Also in this embodiment, the optically transmissive resin 18 may be formed to include the lens 19 above the LED chip 12 to collect and guide the light emitted from the LED chip 12. Alternatively, the optically transmissive resin 18 may be formed to keep the flat emission surface of the optically transmissive resin 18 to refract the light that reaches the emission surface of the optically transmissive resin 18 as such and guide the light outside.

The embodiments of FIGS. 1-8 of the present invention are configured based on the premise that a ground electrode is formed on the lower surface and an anode and a cathode electrode are formed on the upper surface of the LED chip. Therefore, two wires for connecting the upper electrodes on the LED to the metallic films are provided for the anode and the cathode. Depending on the type, the LED chip may have the anode and the cathode that is formed on the lower and the upper surfaces, respectively. In such a case, a single wire is required to connect the upper electrode on the LED to the metallic film. In addition, the metallic film not connected to the electrode on the LED may be formed directly on the surface of the optically transmissive resin, or may not be formed. If there are no unnecessary metallic films formed on the surface of the optically transmissive resin, then two metallic films formed on the surface of the optically transmissive resin are preferably electrically connected to the upper and lower electrodes on the LED chip.

A reflective member may be employed to form a resist layer on the same surface of the optically transmissive resin as the metallic-films-formed surface, but outside of the metallic-films-formed portions. In this case, the light emitted from the LED chip can be reflected at the resist layer and efficiently directed in the emission direction at the surface of the optically transmissive resin. This is particularly effective when a conical reflective surface is not formed around the LED-chip-mounted region.

The surface-mounted light-emitting diode according to the present invention has the following and other advantages.
(1) The surface-mounted light-emitting diode can be made thinner because no printed-circuit board is employed. Thus, its use as a light source for electronic devices such as cell phones can improve the overall thinness of the device and the design flexibility.
(2) As no printed-circuit board is employed, there is no interface having a different thermal expansion coefficient that is formed at the boundary with the optically transmissive resin. This can prevent a malfunction to be caused by factors associated with a stress at an interface, and thus contributes to an improvement in the quality of the device.
(3) The LED chip can be mounted on the bottom in a conical shape having a conical reflective surface. Alternatively, the resist layer can be formed on the same surface of the optically transmissive resin as is the metallic-films-formed surface except outside the metallic-films-formed portions. Accordingly, the light emitted from the LED chip but not directed in the emission direction can be reflected toward the emission direction. This is effective to direct the light emitted from the LED chip efficiently to improve the light extraction efficiency.
(4) The metallic film serving as the electrode for supplying external power to the surface-mounted LED can be located inward from the perimeter of the surface-mounted LED. Accordingly, the surface-mounted LED can be mounted integrally with other components to achieve a high mounting density.
(5) Many surface-mounted LEDs are formed in batches and are finally cut into individual surface-mounted light-emitting diodes without cutting any metallic portions. If many surface-mounted LEDs are formed in different areas on a print-circuit board and then cut into individual surface-mounted LEDs, burrs of copper patterns are caused. In such a case, there may be various problems associated with: preparation of steps for removing the burrs; lack in dimensional stability on products individualized in the step of removing the burrs; reduction of the lifetime of teeth on a dicer/cutter tool by requiring it to cut through the copper patterns; and interference of the burrs with the solder that elevates onto the conductive patterns. These and other problems can be avoided herein to achieve a low-cost, high-quality surface-mounted LED. These are some of the excellent effects achieved by the invention.

Having described the preferred embodiments consistent with the invention, other embodiments and variations consistent with the invention will be apparent to those skilled in the art. Therefore, the invention should not be viewed as limited to the disclosed embodiments but rather should be viewed as limited only by the spirit and scope of the appended claims.

1. A surface-mounted light-emitting diode comprising:
a light-emitting diode chip sealed in an optically transmissive resin;
a plurality of metallic films formed on different locations in a surface of said optically transmissive resin; and
a plurality of electrodes formed on said light-emitting diode chip, wherein said electrodes are connected to respective ones of said metallic films to achieve electrical conduction there between.

2. The surface-mounted light-emitting diode according to claim 1, wherein said light-emitting diode chip is mounted on a first metallic film of said metallic films to achieve electrical conduction between a lower electrode on said light-emitting diode chip and said first metallic film, and at least one wire is connected between at least one upper electrode on said light-emitting diode chip and a second metallic film of said metallic films to achieve electrical conduction between said at least one upper electrode on said light-emitting diode chip and said second metallic film.

3. The surface-mounted light-emitting diode according to claim 2, wherein at least said first metallic film of said metallic films is formed in a conical shape having a bottom and a reflective inner surface, and wherein said light-emitting diode chip is mounted on the bottom.

4. The surface-mounted light-emitting diode according to claim 3, wherein a layer of optically transmissive resin containing a fluorescent material therein is formed inside said conical shape to cover said light-emitting diode chip.

5. The surface-mounted light-emitting diode according to claim 3, wherein a layer of optically transmissive resin containing a diffuser therein is formed inside said conical shape to cover said light-emitting diode chip.

6. The surface-mounted light-emitting diode according to claim 2, wherein an optically transmissive resinous lens is formed above said light-emitting diode chip.

7. The surface-mounted light-emitting diode according to claim 2, wherein at least said first metallic film of said metallic films is planar in shape.

8. The surface-mounted light-emitting diode according to claim 1, wherein said light-emitting diode chip is mounted on an insulator member, and wherein a wire is connected between an upper electrode on said light-emitting diode chip and one of said metallic films to achieve electrical conduction between said upper electrode on said light-emitting diode chip and said one of said metallic films.

9. The surface-mounted light-emitting diode according to claim 7, wherein an optically transmissive resinous lens is formed above said light-emitting diode chip.

10. The surface-mounted light-emitting diode according to claim 7, wherein a resist layer is formed on different areas of the surface of said optically transmissive resin upon which said metallic films are formed.

11. The surface-mounted light-emitting diode according to claim 2, further comprising another wire connected between another upper electrode on said light emitting diode chip and a third metallic film of said plurality of metallic films to achieve electrical conduction between said another upper electrode on said light emitting diode chip and said third metallic film.

12. The surface-mounted light-emitting diode according to claim 3, wherein an optically transmissive resinous lens is formed above said light-emitting diode chip.

13. The surface-mounted light-emitting diode according to claim 4, wherein an optically transmissive resinous lens is formed above said light-emitting diode chip.

14. The surface-mounted light-emitting diode according to claim 8, wherein another wire is connected between another upper electrode on said light-emitting diode chip and another one of said metallic films to achieve electrical conduction between said another upper electrode on said light-emitting diode chip and said another one of said metallic films.

15. The surface-mounted light-emitting diode according to claim 8, wherein an optically transmissive resinous lens is formed above said light-emitting diode chip.

16. The surface-mounted light-emitting diode according to claim 8, wherein a resist layer is formed on different areas of the surface of said optically transmissive resin upon which said metallic films are formed.

17. The surface-mounted light-emitting diode according to claim 9, wherein a resist layer is formed on different areas of the surface of said optically transmissive resin upon which said metallic films are formed.

18. A light-emitting diode comprising:
a light-emitting diode chip located adjacent an optically transmissive resin;
at least one metallic film formed directly on a surface of said optically transmissive resin; and
at least one electrode located on said light-emitting diode chip, wherein said electrode is connected to said metallic film to achieve electrical conduction there between.

19. The light-emitting diode according to claim 18, wherein said light-emitting diode chip is mounted on another metallic film to achieve electrical conduction between a lower electrode on said light-emitting diode chip and said another metallic film, and at least one wire is connected between at least one upper electrode on said light-emitting diode chip and the at least one metallic film to achieve electrical conduction between said at least one upper electrode on said light-emitting diode chip and said at least one metallic film.

20. A method of making a light-emitting diode, comprising:
providing a substrate with recesses;
forming a plurality of metallic films in the recesses of the substrate;
mounting an LED chip to one of the metallic films;
connecting a wire between the LED chip and another one of the metallic films to achieve an electric connection between an electrode on the LED chip and the another one of the metallic films;
placing a resin on the LED chip and metallic films; and
removing the substrate.
